(19) United States
(12) Patent Application Publication
(10) Pub. No.: US 2009/0033495 A1
(43) Pub. Date: Feb. 5, 2009

(54) MOLDABLE RADIO FREQUENCY IDENTIFICATION DEVICE

(76) Inventors: Akash Abraham, Cleveland Heights, OH (US); Ted Hoerig, Strongsville, OH (US)

Correspondence Address: AVERY DENNISON CORPORATION;Patent Group, Law Department - 3 South, P.O. BOX 7090, PASADENA, CA, 91109-7090, US

(21) Appl. No.: 11/833,950

(22) Filed: Aug. 3, 2007

(51) Int. Cl. H01L 23/28

(52) U.S. Cl. 340/572.1; 438/26; 257/E23.116

(57) ABSTRACT

This invention relates to molded plastic article having an in-mold label comprising radio frequency identification (RFID) device, and methods of in-mold labeling. In one embodiment of the invention, an RFID label comprises an RFID inlay and a substrate underneath the RFID inlay. The substrate includes a first surface and a second surface, with the RFID inlay disposed on the first surface. A primer is applied to the first surface including the inlay and the second surface of the substrate. A polymer cover is applied over the primer on the first surface and the second surface using slot die coating.

### TECHNICAL FIELD OF THE INVENTION

This invention relates to molded products with in-mold RFID labels and methods of in-mold labeling.

### BACKGROUND

An RFID label is a smart label that could be used for various purposes such as the identification and tracking of goods. Molded products, such as containers in a warehouse and plastic bins in a manufacturing facility, may require an RFID label because the containers have to be identified in the warehouse and the plastic bins have to be tracked during the manufacturing operation. This can be accomplished by either attaching the label to the surface of the product via an adhesive or fastener solution or by embedding the label into the molded product. Attaching an RFID label to a product using an adhesive or a fastener has the risk of the label separating from the product. The labels in this scenario are not flush with the surface and therefore are subject to various environmental hazards that can cause separation. By making the label an integral part of the molded product and flush with the surface, the chances of the label separating from the product are minimal. Molded labels are useful in creating a discrete, permanent identification method for the plastic molded products.

An RFID inlay or label generally comprises a chip or a “strap” connected to antenna disposed on a substrate made of polymers such as polyethylene terepthalate (PET). RFID labels having a substrate made of material such as PET may be difficult to embed in a plastic product because the PET resin does not bond well with high density polyethylene (HDPE), a resin that is commonly used in the manufacture of molded plastic products such as bins, pallets, and containers. If the RFID label does not bond well with the bulk material, such as HDPE used to make a plastic product, the label may not remain a part of the molded product.

### SUMMARY

This invention relates to molded plastic article having an in-mold label comprising an RFID device, and method of in-mold labeling. In one embodiment of the invention, the label comprises an RFID inlay and a substrate made of a polymer material such as PET underneath the RFID inlay. The substrate including the RFID inlay is chemically primed, and then covered with a polymer such as low density polyethylene (LDPE) resin. Many injection molded products are made from HDPE. The LDPE resin that covers the label can bond with the HDPE resin that is injection molded because they are chemically similar substrates, but the PET and the HDPE are dissimilar resins and do not bond. Because the LDPE covering allows for adhesion of the PET substrate of the label with the dissimilar HDPE resin, the LDPE covering makes the RFID label amenable for inclusion in an injection molded HDPE product

The embodiments of in-mold RFID labels have various configurations. The configurations comprise:

Label before in-mold inclusion in a product:
1. LDPE/Primer/RFID inlay/Primer/LDPE
2. RFID inlay/Primer/LDPE

Label after in-mold inclusion in a product:
3. Face of product/LDPE/Primer/RFID inlay/Primer/LDPE
4. Face of product/RFID inlay/Primer/LDPE
   In the fourth configuration, the LDPE and the face of the injection molded product encapsulate the inlay.

### BRIEF DESCRIPTION OF THE DRAWINGS

FIG. 1 is a cross-sectional view of the first embodiment of the RFID label.

FIG. 2 is a cross-sectional view of the second embodiment of the RFID label.

FIG. 3 is a cross-sectional view of the third embodiment of the RFID label.

FIG. 4 is a cross-sectional view of an embodiment of the RFID label of FIG. 1 included in a molded product.

FIG. 5 is a cross-section view of an embodiment of the RFID label of FIG. 2 included in a molded product.

### DETAILED DESCRIPTION OF PREFERRED EMBODIMENTS

The term “label” as used here refers to a label, tag or ticket. The term “Radio Frequency Identification” or RFID as used here refers to device that receives or transmits data by radio frequency. The RFID device is of any conventional construction and inlays suitable for use in the present invention are produced as described in U.S. Pat. No. 6,951,596. The term RFID label refers to a label that includes an RFID device. The present invention, in one embodiment, relates to the discovery that an RFID label when covered with a polymeric resin that is chemically compatible with the polymer used for making a molded product makes the RFID label amenable for inclusion in the molded product. In a further embodiment, the RFID label covered with a polymeric resin is placed inside a mold and the polymer injected into the mold to form the molded product.

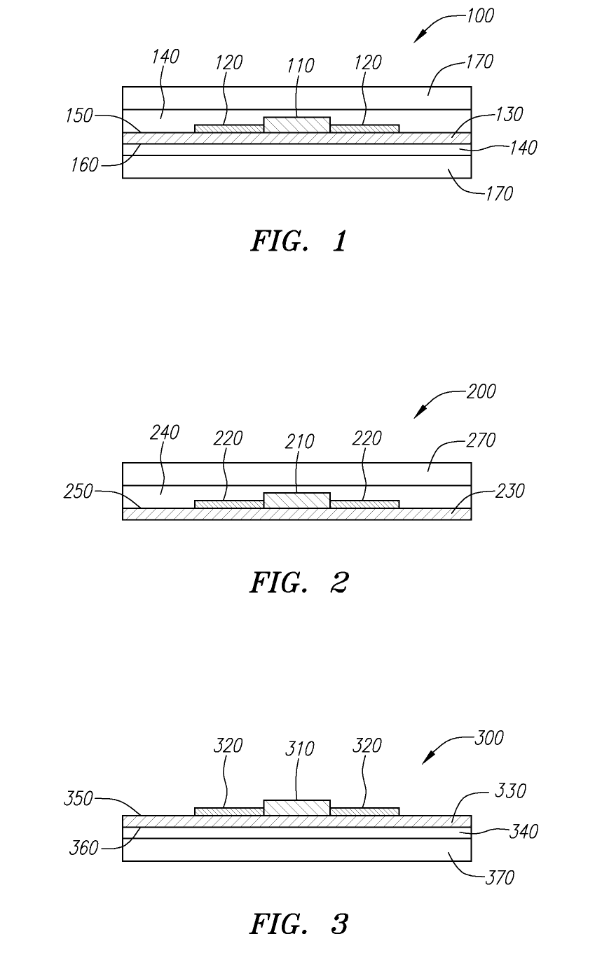

FIG. 1 shows a first embodiment of an RFID label according to the invention. The label, indicated generally at 100, includes an RFID device which comprises an integrated circuit chip 110 connected to an antenna 120. The RFID device is mounted on a substrate 130. A primer 140 is applied to the first surface 150 of the substrate which is the surface that has the RFID device mounted on it, and the second surface 160 of the substrate opposite the first surface. When applying primer to the first surface 150 of the substrate, primer is also applied to the RFID chip 110 and the antenna 120. In one embodiment, the primer is of uniform thickness. In another embodiment, the primer is not of uniform thickness. In a further embodiment, the primer is a water based primer which is not an adhesive. In another embodiment, the primer acts as an adhesion promoter that enhances the surface's acceptance of the resin. In yet another embodiment, the primer serves as an important component of the ultimate adhesion of a polymer to the RFID substrate when making a polymer covered RFID label.

After the application of the primer 140, the RFID label is covered with a polymer 170 using well known techniques such as extrusion and coating. In one embodiment, the polymer 170 is LDPE. In another embodiment, the polymer 170 is polypropylene (PP). In a further embodiment, the polymer 170 is ethyl vinyl acetate (EVA). The polymer 170 can also be mixture of polymeric resins such as LDPE and PP. Slot Die coating is a basic method of applying molten polymeric resin to a substrate. A coating liquid is forced out from a reservoir through a slot by pressure, and transferred to a web. Slot Die coating is a coating with a die against a web. Practical considerations for use of slot die as a coating method are geared to quality needs, e.g., performance, uniformity of coating thickness, freedom from defects, and a uniform surface finish with the desired characteristics.

FIG. 2 shows a second embodiment of the RFID label of the present invention. The label, indicated generally at 200, includes an RFID device which comprises an integrated circuit chip 210 connected to an antenna 220. The RFID device is mounted on a substrate 230. A primer 240 is applied to the first surface 250 of the substrate 230 which is the surface that has the RFID device mounted on it. When applying primer to the first surface 250 of the substrate, primer is also applied to the RFID chip 210 and the antenna 220. After the application of the primer 240, a layer of polymer 270 is added to the first surface 250 of the RFID label using well known techniques such as extrusion and coating.

FIG. 3 shows a third embodiment of the RFID label of the present invention. The label, indicated generally at 300, includes an RFID device which comprises an integrated circuit chip 310 connected to an antenna 320. The RFID device is mounted on a substrate 330. A primer 340 is applied to the second surface 360 of the substrate 330 which is the surface opposite the surface 350 that has the RFID device mounted on it. After the application of the primer 340, a layer of polymer 370 is added to the second surface 360 of the RFID label using well known techniques such as extrusion and coating.

In other embodiments of the present invention, primer is not be used and the polymer is directly applied to the RFID substrate, the RFID chip and/or the antenna. In a further embodiment of the present invention, an adhesive layer is disposed as the top or uppermost layer of the in-mold labels. In another embodiment, the adhesive layer is disposed over outer or exposed surface of the polymer layer. The adhesive layer partially or fully covers the polymer layer. The adhesive layer permits the attachment of the in-mold label to an interior surface of the mold, which prevents the label from displacing or distorting prior to or during the molding process. Any adhesive which is capable of adhering the label to an interior surface of the mold as the molding process is initiated can be utilized. Suitable commercially available adhesives are sold by such commercial sources as Beacon Chemical Company, Inc., Acheson Colloids, Quretech and Northwest Coatings. Examples of such adhesives are Magnacryl 2793 (Beacon), ML 25184 (Acheson), JRX-1068 (Quretech) and U.V.-curable-10152 (Northwest). Other examples of adhesives available from Beacon Chemical Company include Magnacryl UV 2601 Epoxy, Magnacryl 2296, and Magnacryl 2807. Another example of a useful commercially available adhesive material is Rad-Cure UV 1008 (a product of Rad-Cure Corporation identified as a U.V. curable, solvent-free adhesive containing 70-95% w multifunctional acrylate monomers, 5-20% w photoinitiator and 0-5% w surfactants.). In yet another embodiment, the in-mold label of the present invention comprises a carrier which is a release-coated liner having one surface (the release-coated surface) in contact with the otherwise exposed upper surface of the adhesive layer. The carrier is used to protect the upper surface of the adhesive layer during preparation, handling, storage and shipping of the labels. The carrier is removed from the label prior to positioning and adhering the label to an internal surface of the mold. The release-coated liner may comprise a substrate sheet of paper, a polymer film or combinations thereof coated with a release composition.

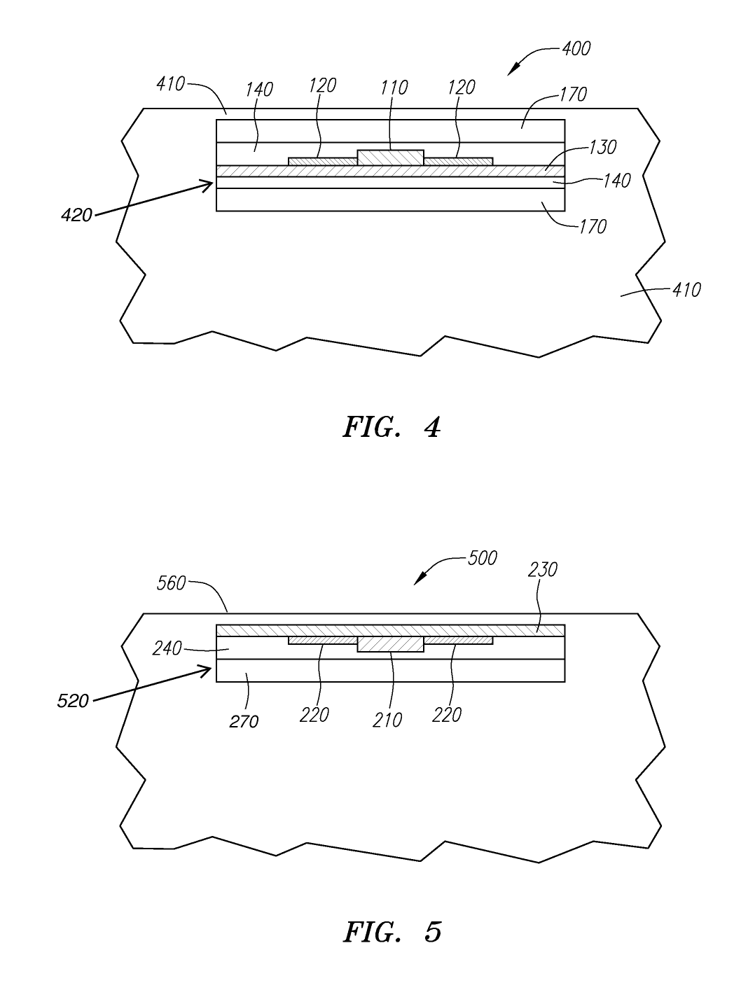

FIG. 4 shows a cross-sectional view of the embodiment of RFID in-mold label of FIG. 1 included in a molded product, indicated generally at 400. The method of including the RFID in-mold label 420 in the molded product comprises placing the RFID label 420 inside the mold proximate to the surface of the mold. In one embodiment, an adhesive is used to maintain the label's position in the mold. In another embodiment, the position of the label in the mold is away from the in-gate of the mold. In yet another embodiment, the position of the label in the mold is the furthest possible location from the in-gate of the mold. The molded product is manufactured by commonly known techniques such as injection or blow molding. In injection molding, the material of construction 410 of the product is injected into the mold to form the molded product 400. In one embodiment, the material of construction is a polymer. In another embodiment, the material of construction is HDPE.

FIG. 5 shows a cross-sectional view of the embodiment of RFID in-mold label of FIG.2 included in a molded product. The product, indicated generally at 500, includes an RFID in-mold label 520. The label 520 is placed near the face 560 of the molded product. The face 560 of the molded product and the LDPE layer 270 encapsulate the RFID inlay. In another embodiment, the label is placed at the face of the molded product so as to be exposed on the face of the product.

### EXAMPLES

The following examples describe the various embodiments of the present invention. Numerous modifications and variations within the scope of the present invention will be apparent to those skilled in the art and the present invention is not limited to the examples given below.

### Example

### LDPE Coat

Inlay stock was coated with primer as shown in FIG. 1. Post priming, the inlay stock was further coated with raw LDPE at 5 ml thickness. The coating was then repeated on the second face of the RFID label to create a sandwich construction. The LDPE coated RFID label was then included in a mold and the mold was filled with HDPE using injection molding to make a molded product. After cooling and setting of the polymer, the molded product was removed from the mold and the RFID label was tested for physical damage and readability. The RFID label did not exhibit any damage, was smooth and readable.

### Example 2

### PP Coat

Inlay stock was coated with primer as shown in FIG. 1. Post priming, the inlay stock was further coated with raw PP at 5 ml thickness. The coating was then repeated on the second face of the RFID label to create a sandwich construction. The PP coated RFID label was then included in a mold and the mold was filled with HDPE using injection molding to make a molded product. After cooling and setting of the polymer, the molded product was removed from the mold and the RFID label was tested for physical damage and readability. The RFID label did not exhibit any damage, was smooth and readable.

The primer used in Examples 1 and 2 is a water-based primer MICA available from Mica Corporation, Shelton, Conn. The water-based primer MICA is non-adhesive, and was utilized to promote chemical bonding of the LDPE resin with the RFID substrate.

Although the present invention has been described with reference to preferred embodiments, workers skilled in the art will recognize that changes may be made in form and detail without departing from the spirit and scope of the invention.

What is claimed is:

1. A radio frequency identification (RFID) label comprising:
a chip, an antenna, and a substrate, said substrate comprising a first surface and a second surface, said chip and said antenna included on said first surface;
a first layer of primer disposed on said first surface including said chip and said antenna; and
a first layer of polymer disposed on said first layer of primer.

2. The RFID label according to claim 1 further comprising:
a second layer of primer disposed on said second surface; and
a second layer of polymer disposed on said second layer of primer.

3. The RFID label according to claim 1 or 2 wherein the primer is water-based.

4. The RFID label according to claim 1 or 2 wherein the primer is non-adhesive.

5. The RFID label according to claim 1 or 2 wherein the primer promotes chemical bonding between the polymer and the substrate.

6. The RFID label according to claim 1 or 2 wherein the polymer is at least one chemical selected from a group consisting of low density polyethylene (LDPE), polypropylene (PP) and ethyl vinyl acetate (EVA).

7. The RFID label according to claim 1 or 2 wherein the polymer is applied by slot die coating.

8. The RFID label according to claim 1 or 2 further comprising an adhesive layer.

9. A molded product comprising an RFID label,
wherein the RFID label comprises
a chip, an antenna, and a substrate, said substrate comprising a first surface and a second surface, said chip and said antenna included on said first surface;
a first layer of primer disposed on said first surface including said chip and said antenna;
a first layer of polymer disposed on said first layer of primer; and
wherein the RFID label is disposed at or near the face of the molded product.

10. The molded product according to claim 9 wherein the RFID label further comprises:
a second layer of primer disposed on said second surface; and
a second layer of polymer disposed on said second layer of primer.

11. The molded product according to claim 9 or 10 wherein the primer is water-based.

12. The molded product according to claim 9 or 10 wherein the primer is non-adhesive.

13. The molded product according to claim 9 or 10 wherein the primer promotes chemical bonding between the polymer and the substrate.

14. The molded product according to claim 9 or 10 wherein the polymer is at least one chemical selected from a group consisting of LDPE, PP and EVA.

15. The molded product according to claim 9 or 10 wherein the polymer is applied by slot die coating.

16. The molded product according to claim 9 or 10 wherein the polymer is chemically compatible with a material of construction of the molded product, whereby the polymer bonds with the material of construction of the molded product.

17. Method of manufacturing a moldable RFID label comprising:
disposing a first layer of primer on a first surface of an RFID device, said device comprising a chip, an antenna, and a substrate, said substrate comprising the first surface and a second surface, said chip and said antenna included on said first surface; and
disposing a first layer of polymer on said first layer of primer.

18. The method according to claim 17 further comprising:
disposing a second layer of primer on said second surface; and
disposing a second layer of polymer on said second layer of primer.

19. The method according to claim 17 or 18 wherein the primer is water-based.

20. The method according to claim 17 or 18 wherein the primer is non-adhesive.

21. The method according to claim 17 or 18 wherein the primer promotes chemical bonding between the polymer and the substrate.

22. The method according to claim 17 or 18 wherein the polymer is at least one chemical selected from a group consisting of LDPE, PP and EVA.

23. The method according to claim 17 or 18 wherein the polymer is applied by slot die coating.

24. Method of manufacturing a molded product comprising:
covering an RFID label with a polymer, said polymer being chemically compatible with a material of construction of the molded product;
including the RFID label in a mold; and
introducing the material of construction of the molded product into the mold.

25. Method according to claim 24 wherein including the RFID label in the mold comprises using an adhesive to attach the in-mold label to an interior surface of the mold.
